(19) United States
(12) Patent Application Publication
(10) Pub. No.: US 2005/0257369 A1
(43) Pub. Date: Nov. 24, 2005

(54) Electronic component extraction tool

(75) Inventors: Christopher G. Daily, Harrisburg, PA (US); Stuart C. Stoner, Lewisberry, PA (US); Douglas M. Johnescu, York, PA (US); Christopher J. Kolivoski, York, PA (US)

Correspondence Address: HARRINGTON & SMITH, LLP, 4 RESEARCH DRIVE, SHELTON, CT, 06484-6212, US

(73) Assignee: FCI Americas Technology, Inc.

(21) Appl. No.: 11/128,931

(22) Filed: May 12, 2005

Related U.S. Application Data
(60) Provisional application No. 60/572,041, filed on May 18, 2004.

(51) Int. Cl. H05K 3/30; B23P 19/00

(52) U.S. Cl. 29/832; 29/426.1; 29/764; 29/762

(57) ABSTRACT

An electronic component extraction tool is provided. The extraction tool comprises two opposing deflectable arms connected to one another, each arm having an end with a first surface adapted to extend under a side edge of an electronic component and a second surface adapted to extend over a side edge of the electronic component. The tool further comprises a latch system comprising at least one latching projection on a first one of the arms adapted to engage a second one of the arms to latch the two arms and the ends in an inwardly deflected electronic component carrying position.

### CROSS-REFERENCE TO RELATED APPLICATION

This application claims priority under 35 U.S.C. §119(e) to U.S. Provisional Application No. 60/572,041 filed May 18, 2004, the disclosure of which is hereby incorporated by reference in its entirety herein.

### BACKGROUND OF THE INVENTION

1. Field of the Invention

The present invention relates to an extraction tool and, more particularly, to an extraction tool for removing an electronic component from another member.

2. Brief Description of Prior Developments

U.S. Pat. Nos. 4,604,796; 4,141,138; 4,215,468 and 3,570,096 each disclose different integrated circuit (IC) or module extractor tools, all of which are herein incorporated by reference in their entirety. Specifically, U.S. Pat. No. 4,604,796 (“the '796 patent”) describes an IC component extraction hand tool, especially designed for plastic chip carriers (PCCs) in a socket. The hand tool of the '796 patent comprises a base member for engaging the socket, a handle on the base member, a resilient wire mounted to the handle which passes through holes in the base member and has hook ends which upon actuation of the wire can be caused to engage the component during an extraction operation.

Further, U.S. Pat. No. 4,141,138 (“the '138 patent”) describes a tool for handling integrated circuits to facilitate their installation on and extraction from circuit boards. In particular, the '138 patent describes that a pair of spaced apart levers are pivotal about integral hinges in a manner to engage opposite ends of the integrated circuit. Moreover, each lever carries a pair of lugs between which the ends of the integrated circuit are gripped. The opposite end of the tool is constructed similarly although with a pair of levers that are closer together in order to handle a smaller integrated circuit.

U.S. Pat. No. 4,215,468 (“the '468 patent”) describes an extraction tool for a packaged IC. The tool of the '468 patent is characterized by gripping means for gripping opposite sides of the IC when the tool is actuated by pulling up on a slider, and for applying a uniform lifting force to the IC when the gripping means contacts the IC, to avoid deforming the IC pins.

Moreover, U.S. Pat. No. 3,570,096 (“the 096 patent”) describes a tool for removing modules from a module mounting rail assembly without disturbing adjacent modules. The tool of the '096 patent is constructed of first and second parallel arms joined by a third transverse arm to permit placement of the first and second arms adjacent the sides of a module to be extracted. The first and second arms each terminate in at least one projection, each projection in turn terminating in an inturned rib to grasp the module for removal. Additional arms, in parallel with the first and second arms, help position the nibs in the mounting rail and tabs may be added to such additional arms to further control the positions of the nibs.

However, despite the above advances, there is still a strong need in the art for an electronic component extraction/insertion tool which is easy to use and which insures the safety of the electronic component being handled by the tool. In particular, there is a need in the art for an electronic component extraction/insertion tool which will insure the safe handling of an electronic component by effectively preventing the electrical component from being accidentally released during its transfer to another location, e.g. a connector. The present invention accomplishes the above needs in the art and also provides other advantages, as will be described in detail below.

### SUMMARY OF THE INVENTION

In accordance with one aspect of the invention, an electronic component extraction tool is provided. The extraction tool comprises two opposing deflectable arms connected to one another, each arm having an end with a first surface adapted to extend under a side edge of an electronic component and a second surface adapted to extend over a side edge of the electronic component. The tool further comprises a latch system comprising at least one latching projection on a first one of the arms adapted to engage a second one of the arms to latch the two arms and the ends in an inwardly deflected electronic component carrying position.

In accordance with another aspect of the invention, an electronic component extraction tool is provided. The extraction tool comprises two opposing deflectable arms connected to one another at a connecting section located at top ends of the opposing arms, with each opposing arm also having a bottom end. The bottom ends of the opposing arms comprise an upper ledge and a lower ledge, with the lower ledge and the upper ledge of each of the bottom ends projecting inward towards the opposite arm. The upper ledge has an upwardly facing ramped surface adapted to extend under a side edge of an electronic component and the lower ledge has a downwardly facing surface adapted to extend over a side edge of the electronic component. Each of said opposing arms comprise a finger contact section. The electronic component extraction tool further comprises a latch system which comprises a first latching projection and a second latching projection. The first latching projection comprises a first latch and extends towards the second latching projection from an inward side of one of said opposing arms proximate a middle portion of the finger contact section and the second latching projection comprises a second latch and extends towards the first latching projection from an inward side of said other opposing arm proximate a middle portion of the finger contact section of that arm. In addition, the first latch and the second latch are adapted to be engaged and locked with each other in order to cause the two arms and said bottom ends to be placed in an inwardly deflected electronic component carrying position. Moreover, the first latching projection further comprises a finger actuated latch release projection, wherein the finger actuated latch is adapted such that when finger actuated latch is deflected the first and second latches of the first latching projection and the second latching projections become detached from one another.

In accordance with yet another aspect of the invention, a method of using an electronic component extraction tool is provided. The method comprises placing the electronic component extraction tool in contact with side edges of opposing sides of an electronic component. The electronic component extraction tool comprises two opposing deflectable arms connected to one another, with each arm having an end with a first surface adapted to extend under the side edges of the opposing sides of the electronic component and a second surface adapted to extend over the side edges of the opposing sides of the electronic component; and a latch system comprising at least one latching projection on a first one of the arms adapted to engage a second one of the arms. The method further comprises deflecting the opposing arms of the extraction tool inward to move the ends towards each other for gripping the electronic component between the two opposing arms on the surfaces of the ends and at the same time for causing the at least one latching projection on the first one of the arms to engage the second one of the arms to latch the two arms and the ends in an inwardly deflected electronic component carrying position. Further, the method also comprises transferring the electronic component gripped by the extraction tool to another location.

### BRIEF DESCRIPTION OF THE DRAWINGS

FIG. 1 is a perspective view of an electronic component extraction tool incorporating features of the present invention;

FIG. 2 is an enlarged front view of an end of one arm of the tool shown in FIG. 1;

FIG. 3 is an enlarged front view of the latching system of the tool shown in FIG. 1;

FIG. 4 is a perspective view of a member used to carry electronic components;

FIG. 5 is a front view of the end of the tool of FIG. 1 shown attached to an electronic component;

FIG. 6 is a perspective view of the tool and electronic component of FIG. 5 showing the electronic component being inserted into an electrical connector;

FIG. 7 is a perspective view of an alternate embodiment of the extraction tool shown in FIG. 1;

FIG. 8 is an enlarged front view of the latching system of the tool shown in FIG. 7; and

FIG. 9 is a rear view of the latching system shown in FIG. 8.

### DETAILED DESCRIPTION OF THE PREFERRED EMBODIMENTS

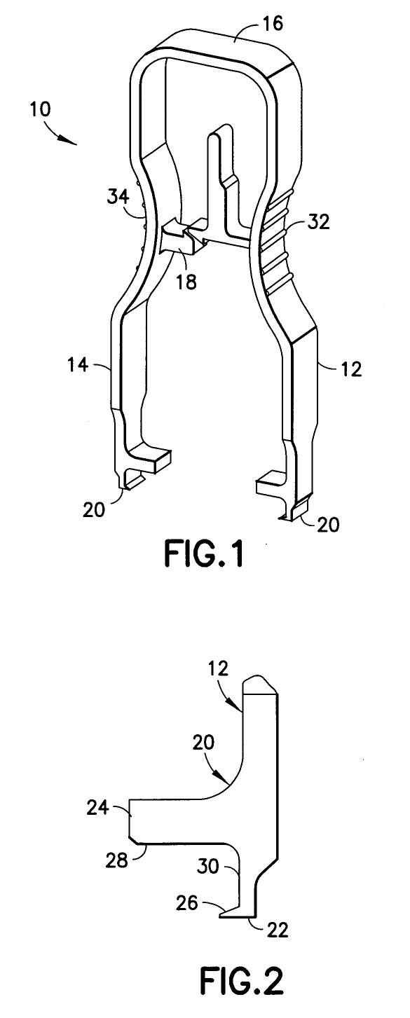

Referring to FIG. 1, there is shown a perspective view of an electronic component extraction tool 10 incorporating features of the present invention. Although the present invention will be described with reference to the exemplary embodiment shown in the drawings, it should be understood that the present invention can be embodied in many alternate forms of embodiments. In addition, any suitable size, shape or type of elements or materials could be used.

The extraction tool 10 generally comprises two opposing deflectable arms 12, 14, a connecting section 16 and a latching system 18. In a preferred embodiment, the extraction tool 10 is comprised of a one-piece member. Preferably, the one-piece member is comprised of injection molded plastic or polymer material. In a preferred embodiment, an anti-static acrylonitrile/butadiene/styrene (ABS) copolymer material is used. However, in alternate embodiments, the tool could be comprised of more than one piece and could be comprised of any suitable type of material(s). For example, in one type of embodiment the tool could comprise a ground strap (not shown) which is attached to the one-piece member.

Each arm 12, 14 comprises an end 20. The ends 20 are substantially identical to each other, but have a reversed or mirror image. In an alternate embodiment, the two ends 20 could be different from each other. Referring also to FIG. 2, each end 20 comprises a lower ledge 22 and an upper ledge 24. The ledges 22, 24 project inward towards the opposite arm 12 or 14. The lower ledge 22 comprises an upwardly facing ramp surface 26. The upper ledges 24 comprises a downward facing surface 28. The ledges 22, 24 form a receiving area 30 which is adapted to receive a side edge of an electronic component.

Referring to FIG. 1, each arm 12, 14 comprises a finger contact section 32, 34. A user can place a finger and a thumb of a same hand in the finger contact section 32, 34 and press inward to deflect the two ends 20 towards each other. The connecting section 16 connects the two arms 12, 14 to each other and provides an internal resilience to allow the two arms 12, 14 to deflect back towards their outward home position (as shown in FIG. 1) when the force from the user's finger and thumb is released (assuming the latching system 18 is not engaged).

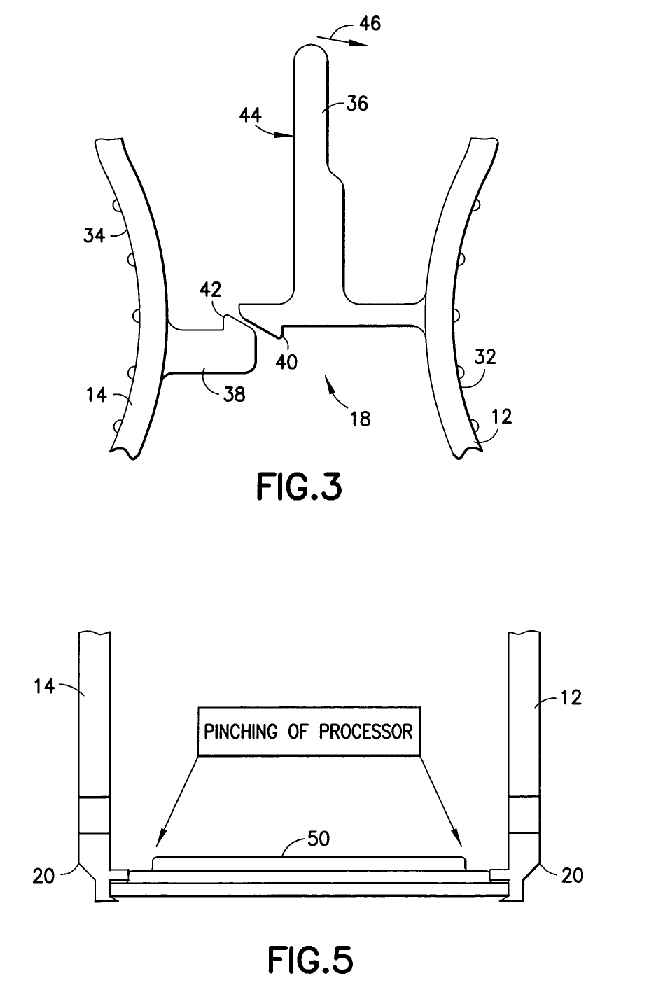

The latching system 18 is generally adapted to latch the two arms 12, 14 in an inwardly deflected electronic component carrying position. Referring also to FIG. 3, the latching system 18 generally comprises a first latching projection 36 and a second latching projection 38. The first latching projection 36 extends towards the second latching projection 38 from an inward side of the first arm 12 proximate the middle of the finger contact section 32. The second latching projection 38 extends towards the first latching projection 36 from an inward side of the second arm 14 proximate the middle of the finger contact section 34. The two latching projections 36, 38 comprise latches 40, 42 which are adapted to engage and lock with each other. The first latching projection 36 also comprises a finger actuated latch release projection 44. In this embodiment, the release projection 44 extends in an upward direction in a space between the top ends of the two arms 12, 14. After the latches 40, 42 are latched with each other, a user can deflect the release projection 44 as indicated by arrow 46, by the user's finger, to deflect the latch 40 upward and thereby unlatch the two latches 40, 42 from each other.

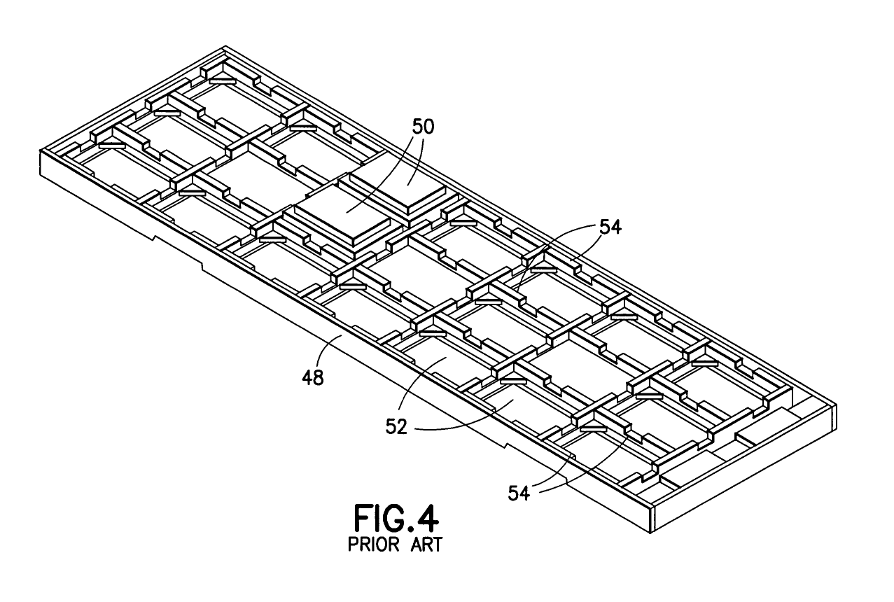

Referring now also to FIG. 4, a perspective view of an electronic component holding member 48 is shown. The holding member 48 is a carrier adapted to carry a plurality of the electronic components 50, such as microprocessors. The holding member 48 has individual electronic component receiving areas 52. The sidewalls of the receiving areas 52 comprises slots 54. The ends 20 of the arms 12, 14 are adapted to be slid through the slots 54 on opposing sides of one of the receiving area 52 to position the ends 20 at opposite side edges of one of the electronic components 50.

Referring also to FIG. 5, after the ends 20 are inserted into the slots 54 of the carrier 48, a user can deflect the arms 12, 14 inward to move the ends 20 towards each other and pinch or grab the electronic component 50 between the two arms. During this process, the latches 40, 42 latch with each other to maintain the arms 12, 14 and the ends 20 in their inwardly deflected electronic component carrying position as shown in FIG. 5.

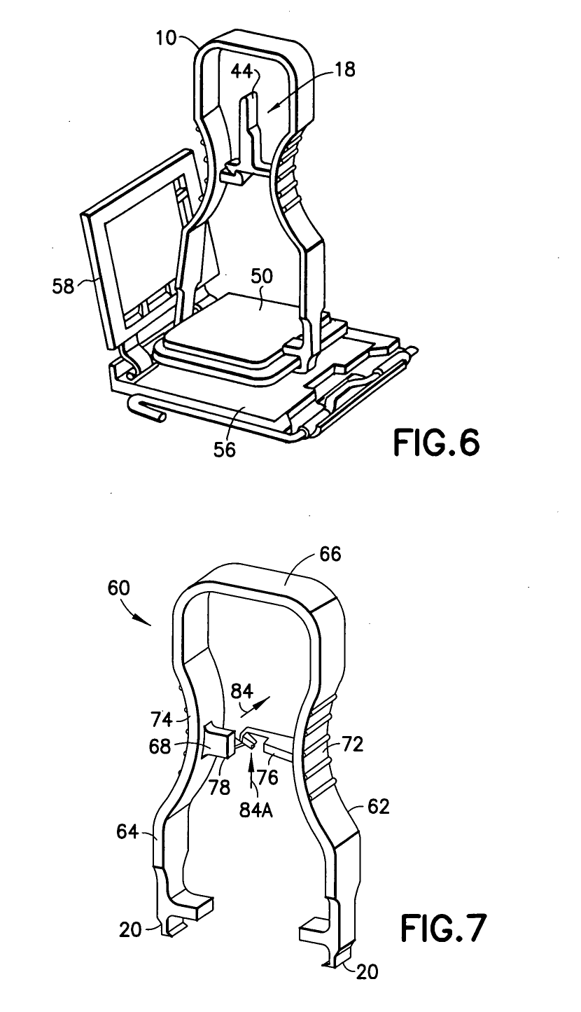

As shown in FIG. 6, the extraction tool 10 with its attached electronic component 50 can then be moved to an electrical connector 56. Because of the latching system 18, the electronic component 50 is prevented from being released from the tool 10 during the step of transferring the electronic component 50 from the holder 48 to the connector 56. This helps to insure that the electronic component 50 will not be accidentally dropped by the assembly line worker and possibly damaged. Once the assembly line worker moves the electronic component 50 to the electrical connector 56, the worker can move the latch release projection 44 to unlatch the two latches 40, 42 from each other and allowed the tool to resiliently deflect the two arms 12, 14 to their home outward position. This releases the engagement between the electronic component 50 and the tool 10. The tool 10 can then be lifted away from the electronic component 50 and the cover 58 of the electrical connector can be closed.

FIG. 7-9 show an alternate embodiment of the present invention. The extraction tool 60 generally comprises two opposing deflectable arms 62, 64, a connecting section 66 and a latching system 68. In a preferred embodiment, the extraction tool 60 is comprised of a one-piece member. Preferably, the one piece member is comprised of injection molded plastic or polymer material. In a preferred embodiment, an ABS material is used which is anti-static. The ends of the arms 62, 64 are identical to the arms 20 described above with reference to the first embodiment.

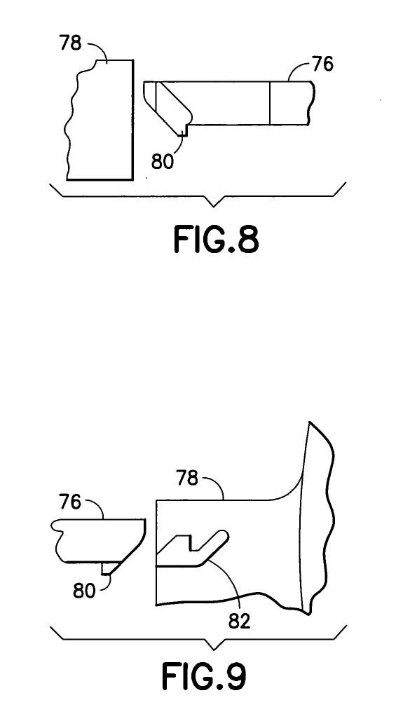

Referring to FIG. 7, the latching system 68 is generally adapted to latch the two arms 62, 64 in an inwardly deflected electronic component carrying position. The latching system 68 generally comprises a first latching projection 76 and a second latching projection 78. The first latching projection 76 extends towards the second latching projection 78 from an inward side of the first arm 62 proximate the middle of the finger contact section 72. The second latching projection 78 extends towards the first latching projection 76 from an inward side of the second arm 64 proximate the middle of the finger contact section 74. Referring to FIGS. 8 and 9, the two latching projections 76, 78 comprise latches 80, 82 which are adapted to engage and lock with each other. In this embodiment, the first latch 82 extends in a forward direction and the second latch 80 extends in a rearward direction.

The first latching projection, in this embodiment, does not comprise a finger actuated latch release projection. After the latches 80, 82 are latched with each other, the user further compresses arms 62, 64. The latch 80 rides in the cam defined by latch 82, which ultimately breaks engagement between latch 80 and latch 82.

It should be understood that the foregoing description is only illustrative of the invention. Various alternatives and modifications can be devised by those skilled in the art without departing from the invention. Accordingly, the present invention is intended to embrace all such alternatives, modifications and variances which fall within the scope of the appended claims.

1. An electronic component extraction tool comprising:
two opposing deflectable arms connected to one another, each arm having an end with a first surface adapted to extend under a side edge of an electronic component and a second surface adapted to extend over a side edge of the electronic component; and
a latch system comprising at least one latching projection on a first one of the arms adapted to engage a second one of the arms to latch the two arms and said ends in an inwardly deflected electronic component carrying position.

2. The electronic component extraction tool of claim 1, wherein each of said ends of said arms comprises an upper ledge and a lower ledge, said lower ledge and said upper ledge of each of said ends projects inward towards the opposite arm, and wherein said lower ledge of each of said ends comprises said first surface and said upper ledge of said each of said ends comprises said second surface.

3. The electronic component extraction tool of claim 2, wherein said first surface of said lower ledge of each end is an upwardly facing ramped surface, and said second surface of each end is a downwardly facing surface.

4. The electronic component extraction tool of claim 1, wherein said opposing arms are connected to one another via a connecting section located at top ends of said opposing arms.

5. The electronic component extraction tool of claim 1, wherein said latching system comprises a first latching projection and a second latching projection, said first latching projection extends from one of said opposing arms towards the second projection, said second latching projection extends from said other opposing arm towards the first projection, and wherein said first projection and second projection are adapted to be engaged and locked with one another.

6. The electronic component extraction tool of claim 5, wherein said first latching projection comprises a first latch and said second latching projection comprises a second latch and wherein said first latch and second latch are adapted to be engaged and locked with each other

7. The electronic component extraction tool of claim 5, wherein each of said opposing arms comprises a finger contact section.

8. The electronic component extraction tool of claim 7, wherein said first latching projection extends towards the second latching projection from an inward side of one of said opposing arms proximate to a middle portion of said finger contact section of that said arm, said second latching projection extends towards the first latching projection from an inward side of said other opposing arm proximate to a middle portion of said finger contact section of that said arm.

9. The electronic component extraction tool of claim 5, wherein the first latching projection further comprises a finger actuated latch release projection, wherein said finger actuated latch release is adapted such that when finger actuated latch release is deflected the first latching projection and the second latching projection become detached from one another.

10. The electronic component extraction tool of claim 9, wherein said finger actuated latch projection extends in an upward direction in a space between top ends of said opposing arms.

11. The electronic component extraction tool of claim 6, wherein said first latch of said first latching projection extends in a forward direction relative to the second latch of said second latching projection, and wherein said second latch extends in a rearward direction relative to the first latch of said first latching projection.

12. The electronic component extraction tool of claim 1, wherein said extraction tool is a one piece member.

13. The electronic component extraction tool of claim 12, wherein said extraction tool is comprised of an injected molded polymer material.

14. The electronic component extraction tool of claim 13, wherein said extraction tool is comprised of an injected molded plastic material.

15. The electronic component extraction tool of claim 12, wherein said extraction tool is comprised of an anti-static acrylonitrile/butadiene/styrene (ABS) material.

16. The electronic component extraction tool of claim 1, wherein said electronic component is a microprocessor chip.

17. An electronic component extraction tool comprising:
two opposing deflectable arms connected to one another at a connecting section located at top ends of said opposing arms, each opposing arm also having a bottom end, said bottom ends of said opposing arms comprise an upper ledge and a lower ledge, said lower ledge and said upper ledge of each of said bottom ends projects inward towards the opposite arm, said upper ledge having an upwardly facing ramped surface adapted to extend under a side edge of an electronic component, said lower ledge having a downwardly facing surface adapted to extend over a side edge of the electronic component, each of said opposing arms comprise a finger contact section; and
a latch system comprising a first latching projection and a second latching projection, said first latching projection comprising a first latch and extends towards the second latching projection from an inward side of one of said opposing arms proximate a middle portion of the finger contact section, said second latching projection comprises a second latch and extends towards the first latching projection from an inward side of said other opposing arm proximate a middle portion of the finger contact section of that arm, said first latch and second latch are adapted to be engaged and locked with each other in order to cause the two arms and said bottom ends to be placed in an inwardly deflected electronic component carrying position,
and wherein the first latching projection further comprises a finger actuated latch release projection, wherein said finger actuated latch is adapted such that when finger actuated latch is deflected the first and second latches of the first latching projection and the second latching projections become detached from one another.

18. The electronic component extraction tool of claim 17, wherein said extraction tool is a one piece member comprised of an anti-static ABS material.

19. A method of using an electronic component extraction tool, comprising:
placing said electronic component extraction tool in contact with side edges of opposing sides of an electronic component, said electronic component extraction tool comprising two opposing deflectable arms connected to one another, each arm having an end with a first surface adapted to extend under said side edges of said opposing sides of the electronic component and a second surface adapted to extend over said side edges of said opposing sides of the electronic component; and a latch system comprising at least one latching projection on a first one of the arms adapted to engage a second one of the arms;
deflecting said opposing arms of said extraction tool inward to move said ends towards each other for gripping said electronic component between the two opposing arms on said surfaces of said ends and at the same time for causing said at least one latching projection on a first one of the arms to engage a second one of the arms to latch the two arms and the ends in an inwardly deflected electronic component carrying position; and
transferring said electronic component gripped by said extraction tool to another location.

20. The method of claim 19, wherein the transferring step comprises:
lifting said extraction tool which is gripping said electronic component away from an electronic component holding member;
positioning the gripped electronic component with an electrical connector;
releasing the electronic component from the extraction tool for use with the electrical connector by disengaging the latching engagement between said two opposing arms; and
lifting said extraction tool away from said electrical connector.
